(19) United States
(12) Patent Application Publication
(10) Pub. No.: US 2006/0118041 A1
(43) Pub. Date: Jun. 8, 2006

(54) Guard ring

(76) Inventor: Chien-Hsin Lai, Kaohsiung Hsien (TW)

Correspondence Address: J C PATENTS, INC., 4 VENTURE, SUITE 250, IRVINE, CA, 92618, US

(21) Appl. No.: 11/009,185

(22) Filed: Dec. 8, 2004

(51) Int. Cl. C23C 16/00

(52) U.S. Cl. 118/715

(57) ABSTRACT

A guard ring for a deposition apparatus, wherein when a wafer is placed on a deposition apparatus and the guard ring is placed to surround the wafer, the a top surface of the guard ring adjacent to the wafer is higher than or equal to that of the wafer. Moreover, when a wafer is placed on the deposition apparatus and the guard ring is placed to surround the wafer, a distance between the guard ring and the wafer is less than 0.7 millimeters. The guard ring according to the present invention can protect the sidewall of the wafer from having lateral deposition so as to increase the planar level of the deposited thin film and the yield of the deposition process.

### BACKGROUND OF THE INVENTION

1. Field of Invention

The present invention relates to a guard ring. More particularly, the present invention relates to a guard ring for a deposition apparatus.

2. Description of Related Art

The thin film deposition technology has been commercially widely used in semiconductor industry. The thin film deposition technology includes physical vapor deposition (PVD) and chemical vapor deposition (CVD). The former technology utilizes the physical phenomenon to perform thin film deposition and the latter technology utilizes the chemical reaction to perform thin film deposition. Nevertheless, no matter what kind of the vapor deposition process is performed, the deposition process should be performed on a deposition apparatus.

FIG. 1 is a cross-sectional view showing a conventional deposition apparatus applied in a deposition process. As shown in FIG. 1, the deposition apparatus 100 comprises at least a carrier 110 and a guard ring 120. The carrier 110 possesses supporting surface S1 and a sidewall S2 and the carrier 110 further has a laterally extending portion. A wafer 130 waiting for the deposition process is placed on the supporting surface S1 and the guard ring 120 is placed on the laterally extending portion of the carrier 110. Moreover, for the plasma enhanced chemical apor deposition (PECVD) or high density plasma enhanced chemical vapor deposition (HDPCVD), the guard ring 120 is used to protect the lower portion of the reaction chamber from being bombarded by plasma.

FIG. 2 is cross-sectional a view showing a wafer during a dual damascene process is performed. As shown in FIG. 2, conventionally, in dual damascene process, multi thin films are sequentially deposited over the wafer 130. For example, a silicon nitride film 210, a fluorinated silicon glass (FSG) film 220, a silicon oxynitride film 230 and the other fluorinated silicon glass film 240 are sequentially formed over the wafer 130. Then, a photolithography process is performed to form a via hole 242 and a dual damascene opening 244 in the multi thin films previously formed. Thereafter, a metal material fills the via hole 242 and the dual damascene opening 244 to form metal plugs 252 and 254 respectively. The plug 254 can be electively connected to the previously formed metal layer 260, such as contact point of the device.

However, during the thin film deposition process shown in FIG. 2, since a top surface 120a of the guard ring 120 shown in FIG. 1 which is adjacent to the wafer 130 is lower than a top surface 130a of the wafer 130 and the distance d between the guard ring 120 and the wafer 130 is relatively large, the lateral deposition 200 shown in FIG. 3 on the sidewall 130b of the wafer 130 is formed with the deposition of the multi thin films including the films 210, 220, 230 and 240 are performed. Apparently, the lateral deposition formed on the sidewall 130b of the wafer 130 will affect the planar level around peripheral region of the wafer 130 and will easily induce the peeling problem of the thin film deposited on the wafer 130.

### SUMMARY OF THE INVETION

Accordingly, the present invention provides a guard ring for a deposition apparatus capable of preventing the lateral deposition on the sidewall of the wafer to relieve the peeling problem of thin films formed on the wafer.

The present invention also provides a guard ring placed to surround a wafer in a deposition apparatus and the top surface of the guard ring adjacent to the wafer is higher than or equal to that of the wafer.

The present invention provides a guard ring for a deposition apparatus, wherein when a wafer is placed on a deposition apparatus and the guard ring is placed to surround the wafer, the a top surface of the guard ring adjacent to the wafer is higher than or equal to that of the wafer.

In the present invention, the distance between the wafer and the guard ring is of about 0.7 millimeters and the inner diameter of the guard ring is of about 300.7±0.1 millimeters. Moreover, the diameter of the wafer is of about 300±0.3 millimeters and the deposition apparatus can be a chemical vapor deposition apparatus. Further, the guard ring can be made of ceramics.

The present invention also provides a guard ring for a deposition apparatus, wherein when a wafer is placed on the deposition apparatus and the guard ring is placed to surround the wafer, a distance between the guard ring and the wafer is less than 0.7 millimeters.

In the present invention, the inner diameter of the guard ring is of about 300.7±0.1 millimeters and the diameter of the wafer is of about 300±0.3 millimeters. The deposition apparatus can be a chemical vapor deposition apparatus and the guard ring can be made of ceramics.

Since the top surface of the guard ring adjacent to the wafer is higher than or equal to that of the wafer and the inner edge of the guard ring is closed to the peripheral region of the wafer, the lateral deposition phenomenon happening on the sidewall of the wafer can be compressed during the deposition process. Therefore, the planar level and the yield of the thin film deposition result can be increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view showing a conventional deposition apparatus applied in a deposition process.

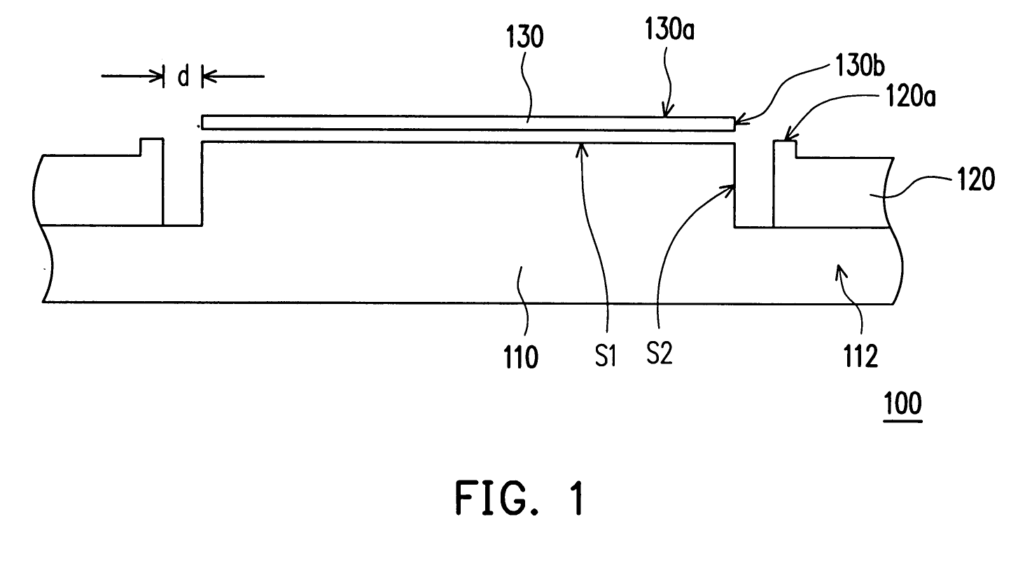

FIG. 2 is a cross-sectional view showing a wafer during a dual damascene process is performed.

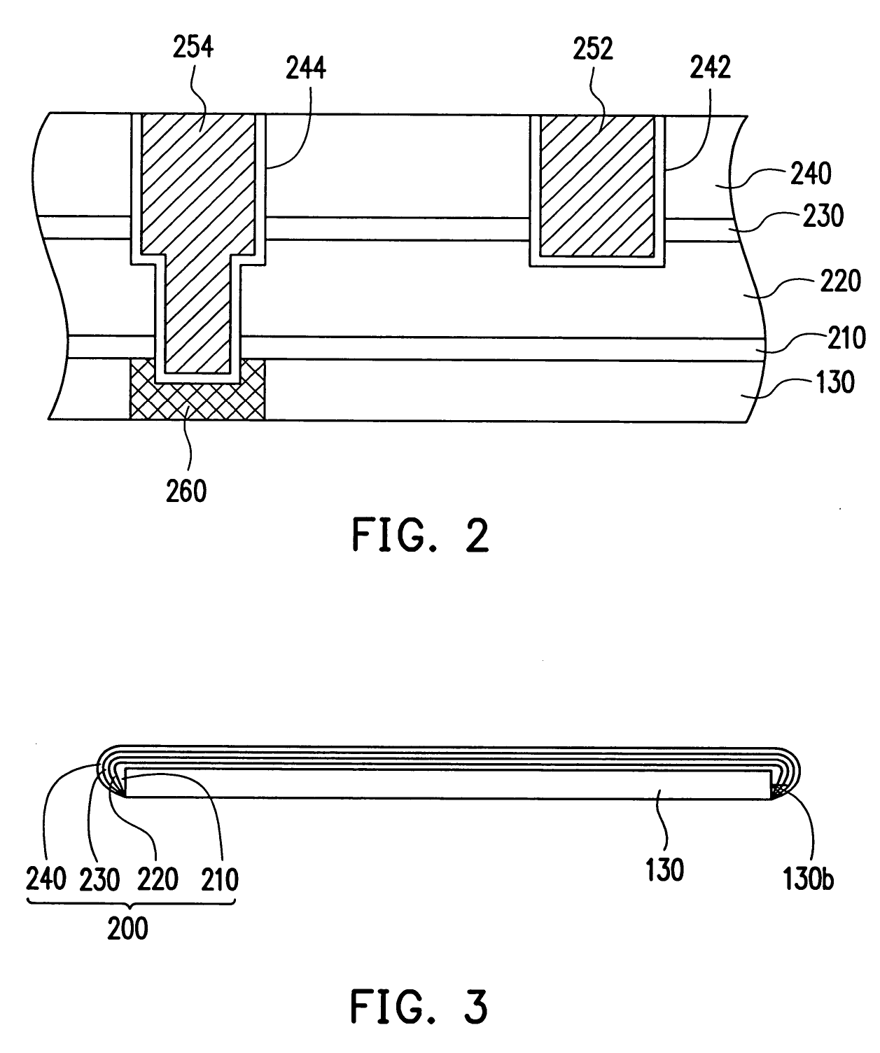

FIG. 3 is a cross-sectional view of a wafer having lateral deposition on the sidewall of the wafer during the deposition process.

FIGS. 4A through 4B are cross-sectional views of a deposition apparatus according to a preferred embodiment of the present invention.

FIG. 5 is a top view of a deposition apparatus according to a preferred embodiment of the present invention.

FIG. 6A is a top view of sampling peripheral region of a wafer after a thin film deposition process using a guard ring according to the present invention.

FIG. 6B is a cross-sectional view of the wafer shown in FIG. 6A.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

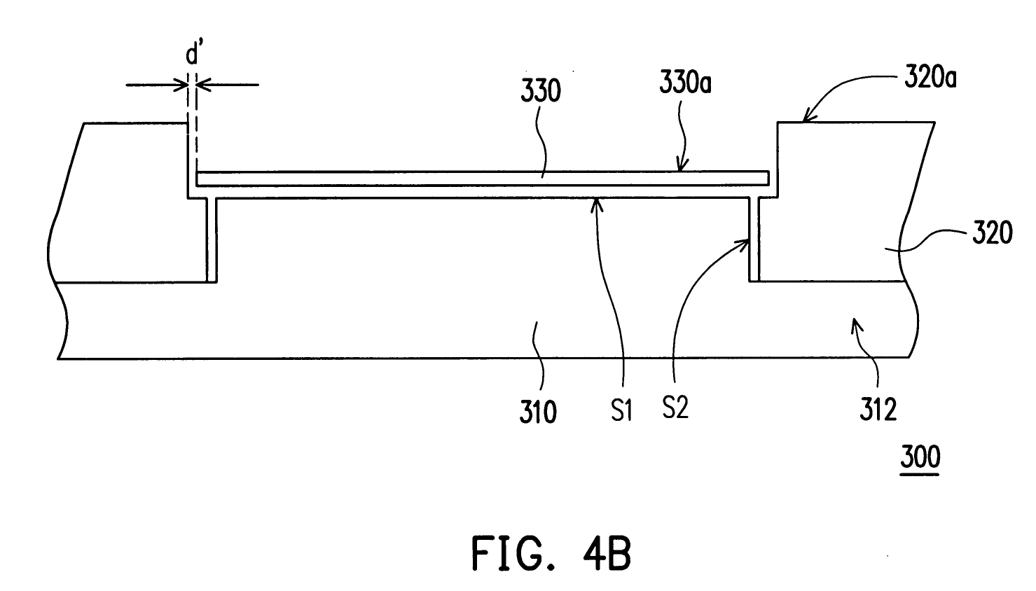

FIGS. 4A through 4B are cross-sectional views of a deposition apparatus according to a preferred embodiment of the present invention.

As shown in FIG. 4A, a deposition apparatus 300 comprises at least a carrier 320 and a guard ring 320, wherein the deposition apparatus 300 can be, for example, an apparatus for performing a plasma enhanced chemical vapor deposition (PECVD) process or a high density plasma enhanced chemical vapor deposition (HDPCVD).

The carrier 310 comprises a supporting surface S1 and a sidewall S2 and the carrier 310 further has a laterally extending portion 312. A wafer waiting 330 for the deposition process is placed on the supporting surface S1. The carrier 310 can be, for example, an E-chuck type carrier or a pedestal type carrier, wherein the E-chuck carrier utilizes the static electricity to carry the wafer 330.

Moreover, the guard ring 320 is placed on the laterally extending portion 320 of the carrier 310. For the PECVD process or HDPCVD process, the guard ring 320 is used to protect the lower portion of the reaction chamber from being bombarded by the plasma. The guard ring 320 can be, for example, made of ceramics.

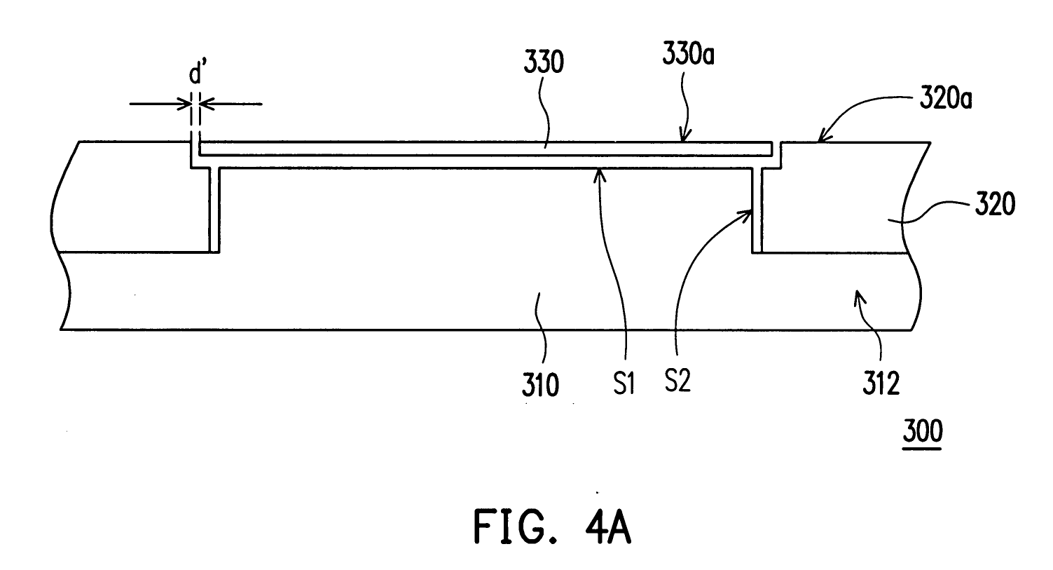

Notably, when a wafer 330 is placed on the deposition apparatus 300 and the guard ring 320 is placed to surround the wafer 330, a top surface 320a of the guard ring 320 adjacent to the wafer 330 is higher than or equal to a top surface 330a of the wafer 330. That is, the top surface 320a of the guard ring 320 according to the present invention adjacent to the wafer 330 and the top surface 330a of the wafer 330 can be at the same plane (as shown in FIG. 4A), or the top surface 320a of the guard ring 320 according to the present invention adjacent to the wafer 330 is higher than the top surface 330a of the wafer 330 (as shown in FIG. 4B). Since the top surface 320a of the guard ring 320 is higher than or equal to that of the wafer 330, the guard ring 320 according to the present invention not only can effectively protect the lower portion of reaction chamber but also can effectively protect the sidewall of the wafer 330 from forming the lateral deposition 200 (as shown in FIG. 3) thereon.

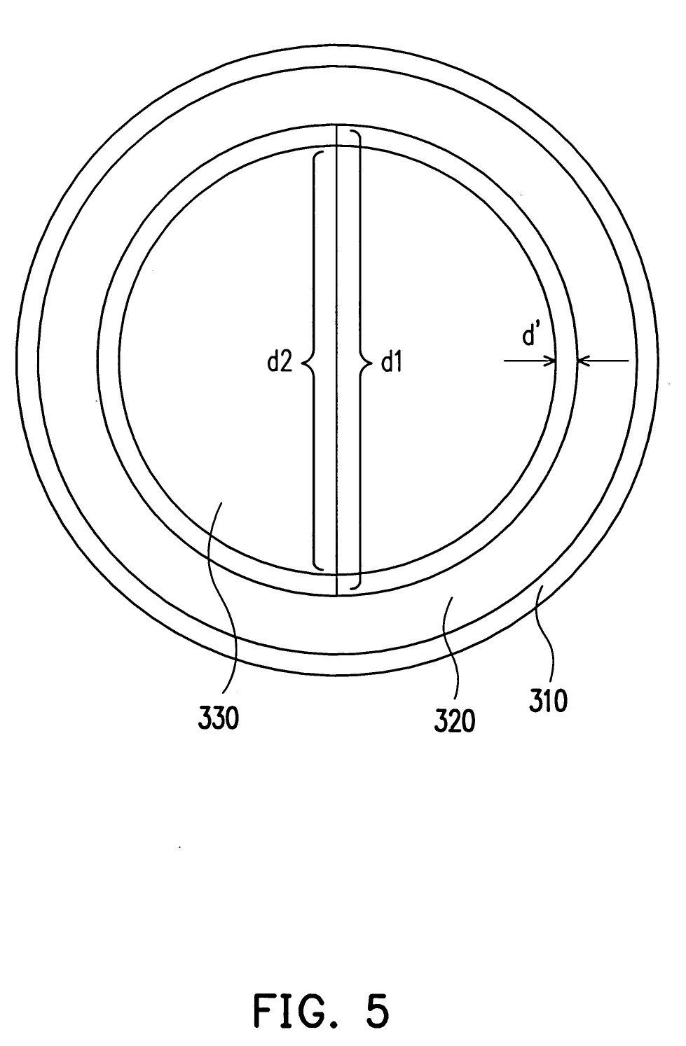

In another embodiment of the present invention, the problem of the lateral deposition on the sidewall of the wafer can be overcome by decreasing the distance d′ between the guard ring 320 and the wafer 330, besides using the guard ring 320 having a relatively higher top surface with respect to the top surface of the wafer. This embodiment is detail described hereafter accompanying with FIG. 5 showing a top view of a deposition apparatus according to a preferred embodiment of the present invention.

As shown in FIG. 5, the distance d′ between the guard ring 320 and the wafer 330 is decreased and the distance d′ is less than 0.7 millimeters. In the other preferred embodiment, the inner diameter d1 of the guard ring 320 is of about 300.7±0.1 millimeters and the diameter d2 of the wafer 330 is of about 300±0.3 millimeters. In the above case, the distance d′ between the guard ring 320 and the wafer 330 is less than 0.7 millimeters. Therefore, the distance d′ between the guard ring 320 and the wafer 330 is decreased. That is, the sidewall of the wafer 330 is very closed to the inner sidewall of the guard ring 320 so as to effectively prevent the lateral deposition on the sidewall of the wafer 330 during the process of the thin film deposition.

Hence, under the case that either the guard ring possesses a relatively higher top surface with respect to the top surface of the wafer, or the distance d′ between the guard ring and the wafer is decreased, or the guard ring possesses a relatively higher top surface with respect to the top surface of the wafer and the distance d′ between the guard ring and the wafer is decreased, the guard ring according to the present invention not only can effectively protect the lower portion of the reaction chamber but also can effectively prevent the lateral deposition on the sidewall of the wafer so as to alleviate the easily peeling problem of the deposited thin film.

The following is a description of a thin film deposition process using the guard ring according to the present invention to proof that the guard ring truly do overcome the problem of lateral deposition on the sidewall of the wafer.

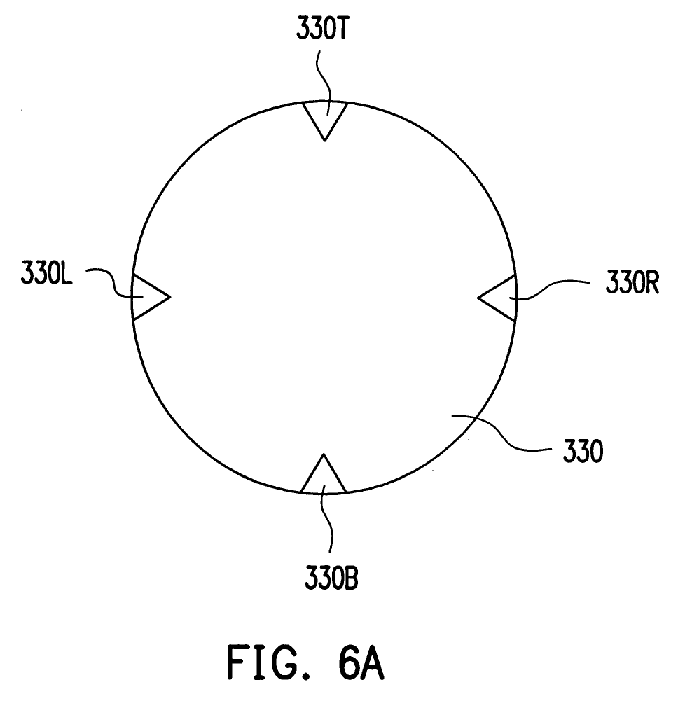

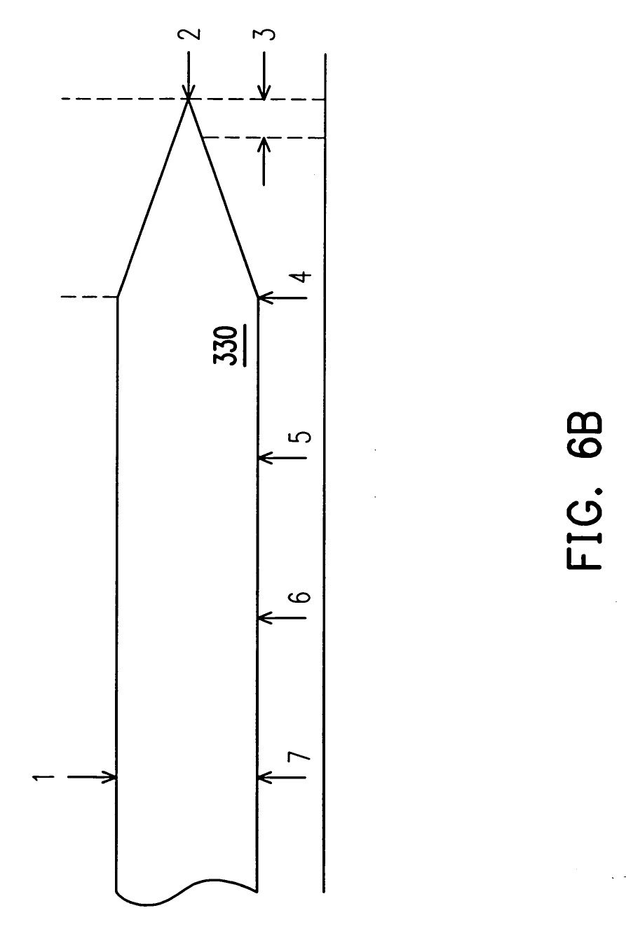

FIG. 6A is a top view of sampling peripheral region of a wafer after a thin film deposition process using a guard ring according to the present invention. FIG. 6B is a cross-sectional view of the wafer shown in FIG. 6A.

Referring to FIG. 6A together with FIG. 6B, in this experiment, when the thin film deposition process is performed, the guard ring according to the present invention is used to protect the sidewall of the wafer from having lateral deposition. After the thin film deposition process, testing samples 330T, 330 B, 330L and 330R shown in FIG. 6A are cut off from four different peripheral portions of the wafer 330. The way to sample the testing samples comprises steps of randomly choosing a diameter line of the wafer 330, sampling the peripheral regions on both ends of the diameter line of the wafer 300, choosing another diameter line orthogonal to the previously chosen diameter line, and then sampling the peripheral regions on both ends of later chosen diameter line. Thereafter, for each testing sample, there are seven testing points labeled from 1 through 7 are selected for measuring the thickness of the thin film (as shown in FIG. 6B). Moreover, the distance between the testing point 1 and the testing point 4 is 3 millimeters, the distance between the testing point 3 and the testing point 2 is 0.2 millimeters, the distance between the testing point 5 and the testing point 4 is 1 millimeters, the distance between the testing point 6 and the testing point 4 is 2 millimeters and the distance between the testing point 7 and the testing point 4 is 3 millimeters. The results of the measurements are shown in Table 1. As shown in Table 1, it further lists the measurement results by using conventional guard ring.

TABLE 1

| | 330T-1 | 330T-2 | 330T-3 | 330T-4 | 330T-5 | 330T-6 | 330T-7 |
|---|---|---|---|---|---|---|---|
| guard ring of the invention | 8063 | 777 | 0 | 0 | 0 | 0 | 0 |
| conventional guard ring | 9134 | 4768 | 2705 | 670 | 280 | 0 | 0 |
| | 330B-1 | 330B-2 | 330B-3 | 330B-4 | 330B-5 | 330B-6 | 330B-7 |
| guard ring of the invention | 8290 | 2625 | 857 | 300 | 0 | 0 | 0 |
| conventional guard ring | 9134 | 5267 | 2906 | 670 | 0 | 0 | 0 |
| | 330C-1 | 330C-2 | 330C-3 | 330C-4 | 330C-5 | 330C-6 | 330C-7 |
| guard ring of the invention | 7915 | 1754 | 200 | 120 | 0 | 0 | 0 |
| conventional guard ring | 9067 | 3134 | 1795 | 442 | 0 | 0 | 0 |
| | 330D-1 | 330D-2 | 330D-3 | 330D-4 | 330D-5 | 330D-6 | 330D-7 |
| guard ring of the invention | 8451 | 3094 | 1112 | 300 | 0 | 0 | 0 |
| conventional guard ring | 9080 | 4326 | 2598 | 415 | 0 | 0 | 0 |

As shown in Table 1, in the testing sample 300T, the testing point 1 is at the position near the central region of the wafer and the thickness of the thin film formed by using the deposition apparatus accompanying with the guard ring according to the invention is not much different from that of the thin film formed by using the deposition apparatus accompanying with the conventional guard ring. Therefore, the guard ring according to the present invention does not affect the thickness of the thin film on the central region of the wafer. The testing point 2 is at the position near the peripheral region of the wafer and the thickness of the lateral deposition is extremely decreased by using the deposition apparatus accompanying with the guard ring according to the invention with respect to the thickness of the lateral deposition by using the deposition apparatus accompanying with the conventional guard ring. The testing points 3 through 7 are at the sidewall portion or at the bottom portion of the wafer so that there is few thin film deposited on the sidewall portion or at the bottom portion of the wafer. Notably, by using the deposition apparatus accompanying with the guard ring according to the present invention, the problem of the thin film deposited on the sidewall portion or at the bottom portion of the wafer can be effectively overcome, especially at testing point 3. Comparing with the result by using the deposition apparatus accompanying with the conventional guard ring, the using guard ring according to the present invention can effectively prevent the lateral deposition phenomenon.

The measurement results of the testing points on other testing samples 330L, 330R and 330B also show the same tendency as the measurement results of the testing points 1 through 7 of testing sample 330T do. That is, by using the deposition apparatus accompanying with the guard ring according to the present invention, the problem of the lateral deposition and the thin film peeling can be overcome.

Altogether, the present invention possesses at least following advantages: (1) the guard ring of the present invention can prevent the sidewall of the wafer from having unnecessary thin film deposition; (2) the guard ring of the present invention can improve the planar level of the thin film formed on the wafer; (3) the guard ring of the present invention can effectively prevent the thin film form having peeling phenomenon.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is :

1. A guard ring for a deposition apparatus, wherein when a wafer is placed on a deposition apparatus and the guard ring is placed to surround the wafer, the a top surface of the guard ring adjacent to the wafer is higher than or equal to that of the wafer.

2. The guard ring of claim 1, wherein a distance between the wafer and the guard ring is of about 0.7 millimeters.

3. The guard ring of claim 2, wherein an inner diameter of the guard ring is of about 300.7±0.1 millimeters.

4. The guard ring of claim 2, wherein a diameter of the wafer is of about 300±0.3 millimeters.

5. The guard ring of claim 1, wherein the deposition apparatus can be a chemical vapor deposition apparatus.

6. The guard ring of claim 1, wherein the guard ring can be made of ceramics.

7. A guard ring for a deposition apparatus, wherein when a wafer is placed on the deposition apparatus and the guard ring is placed to surround the wafer, a distance between the guard ring and the wafer is less than 0.7 millimeters.

8. The guard ring of claim 7, wherein an inner diameter of the guard ring is of about 300.7±0.1 millimeters.

9. The guard ring of claim 7, wherein a diameter of the wafer is of about 300±0.3 millimeters.

10. The guard ring of claim 7, wherein the deposition apparatus can be a chemical vapor deposition apparatus.

11. The guard ring of claim 7, wherein the guard ring can be made of ceramics.
